(19) United States
(12) Patent Application Publication
(10) Pub. No.: US 2021/0202369 A1
(43) Pub. Date: Jul. 1, 2021

(54) ELECTRONIC MODULE

(71) Applicant: SHINDENGEN ELECTRIC MANUFACTURING CO., LTD., Tokyo (JP)

(72) Inventors: Kosuke IKEDA, Hanno-shi (JP); Osamu MATSUZAKI, Hanno-shi (JP)

(73) Assignee: SHINDENGEN ELECTRIC MANUFACTURING CO., LTD., Tokyo (JP)

(21) Appl. No.: 16/077,905

(22) PCT Filed: Jul. 14, 2017
(86) PCT No.: PCT/JP2017/025644

§ 371 Date: Aug. 14, 2018

(51) Int. Cl. H01L 23/498; H01L 23/495; H01L 23/538; H01L 25/07; H01L 23/00

(52) U.S. Cl. CPC H01L 23/49861; H01L 23/49575; H01L 23/49833; H01L 23/49838; H01L 2924/13055; H01L 25/071; H01L 24/32; H01L 2224/32225; H01L 2924/13091; H01L 23/5385

(57) ABSTRACT

An electronic module has a first substrate 11, an electronic element 13 provided on one side of the first substrate 13, a second substrate 21 provided on one side of the electronic element 13 and a positioning part 200 extending from the first substrate 11 to one side and abutting a circumferential part of the second substrate 21, or extending from the second substrate 21 to the other side and abutting against a circumferential part of the first substrate 11.

### TECHNICAL FIELD

The present invention relates to an electronic module having a first substrate and a second substrate provided on one side of the first substrate.

### BACKGROUND ART

An electronic module in which a plurality of electronic elements is provided in a sealing resin is conventionally known (see, for example, Japanese Patent Application Laid-Open No. 2014-45157). Such an electronic module may be provided with a first substrate, an electronic element provided on one side of the first substrate, and a second substrate provided on one side of the electronic element.

When adopting the first substrate and the second substrate described above, in particular, when the sizes in the surface direction of the first substrate and the second substrate are larger, jigs are used to prevent a deviation in the surface direction between the first substrate and the second substrate and, consequently, keep the first substrate and the second substrate in parallel.

### SUMMARY OF INVENTION

### Technical Problem

The present invention provides an electronic module capable of keeping a first substrate and a second substrate in parallel without using jigs.

### Solution to Problem

An electronic module according to the present invention may comprise:

a first substrate;

an electronic element provided on one side of the first substrate;

a second substrate provided on one side of the electronic element; and

a positioning part extending from the first substrate to one side and abutting a circumferential part of the second substrate, or extending from the second substrate to the other side and abutting against a circumferential part of the first substrate.

In the electronic module according to the present invention,

the positioning part may have a protrusion part protruding inwardly,

when the positioning part extends from the first substrate to one side and abuts the circumferential part of the second substrate, the protrusion part may abut a surface of the other side of the second substrate, and

when the positioning part extends from the second substrate to the other side and abuts against the circumferential part of the first substrate, the protrusion part may abut a surface of one side of the first substrate.

The electronic module, according to the present invention, may further comprise

a first conductive layer provided on one side of the first substrate; and

a second conductive layer provided on the other side of the second substrate, and wherein

when the positioning part extends from the first substrate to one side and abuts the circumferential part of the second substrate, the protrusion part may abut a circumferential part of the second conductive layer, and

when the positioning part extends from the second substrate to the other side and abuts against the circumferential part of the first substrate, the protrusion part may abut a circumferential part of the first conductive layer.

In the electronic module according to the present invention,

when the positioning part extends from the first substrate to one side and abuts the circumferential part of the second substrate, the positioning part may be fixed to a surface of one side of the first substrate, and

when the positioning part extends from the second substrate to the other side and abuts against the circumferential part of the first substrate, the positioning part may be fixed to a surface of the other side of the second substrate.

In the electronic module according to the present invention,

when the positioning part extends from the first substrate to one side and abuts the circumferential part of the second substrate, the positioning part may be fixed to the first substrate with bonding material,

when the positioning part extends from the second substrate to the other side and abuts against the circumferential part of the first substrate, the positioning part may be fixed to the second substrate with bonding material,

the electronic element may be fixed to the first substrate or the second substrate with conductive adhesive, and

melting point of the bonding material may be higher than melting point of the conductive adhesive.

In the electronic module according to the present invention,

the positioning part may be formed of a lead frame, and

the positioning part may have a lead frame proximal end part extending in a surface direction, and a lead frame extension part provided on the lead frame proximal end part via a lead frame bent part and extending to one side or the other side.

In the electronic module according to the present invention,

wherein a tip of the positioning part may be tapered.

In the electronic module according to the present invention,

the electronic element may have a first electronic element and a second electronic element provided on one side of the first electronic element, and

a first connection body may be provided between the first electronic element and the second electronic element, the first connection body electrically connecting the first electronic element with the second electronic element.

### Advantageous Effects of Invention

As an aspect of the present invention, when employing an aspect in which there is a positioning part that extends from the first substrate to one side and abuts a circumferential part of the second substrate or extends from the second substrate to the other side and abuts the circumferential part of the first substrate, it is possible to prevent the deviation in the surface direction between the first substrate and the second substrate without using jigs and, consequently, to keep the first substrate and the second substrate in parallel.

### BRIEF DESCRIPTION OF DRAWINGS

FIG. 1(a) is a longitudinal sectional view of an electronic module which can be used in a first embodiment of the present invention. FIG. 1(b) is a plan view of the electronic module shown in FIG. 1(a). A sealing part is not shown in FIG. 1(b), and the sealing part is not shown in the plan views and the bottom views in the following figures.

FIG. 2 is a longitudinal sectional view of an electronic module that can be used in the first embodiment of the present invention, and is a longitudinal sectional view of an electronic module different from the one of the aspect shown in FIG. 1.

FIG. 3 is a longitudinal sectional view of an electronic module that can be used in the first embodiment of the present invention, and is a longitudinal sectional view of an electronic module different from the ones of the aspects shown in FIG. 1 and FIG. 2.

FIG. 4 is a plan view showing first connection body and the like which can be used in the first embodiment of the present invention.

FIG. 5(a) is a longitudinal sectional view of an electronic module of yet another aspect that can be used in the first embodiment of the present invention. FIG. 5(b) is a plan view of the electronic module shown in FIG. 5(a).

FIG. 6(a) is a longitudinal sectional view of an electronic module that can be used in a second embodiment of the present invention. FIG. 6(b) is a bottom view of the electronic module shown in FIG. 6(a).

FIG. 7(a) is a longitudinal sectional view of an electronic module that can be used in a third embodiment of the present invention. FIG. 7(b) is a plan view of the electronic module shown in FIG. 1(a).

FIG. 8(a) is the longitudinal sectional view of the electronic module that can be used in the third embodiment of the present invention. FIG. 8(b) is a bottom view of the electronic module shown in FIG. 7(a).

FIG. 9(a) is the long sectional view of an electronic module that can be used in a fourth embodiment of the present invention.

FIG. 9(b) is a plan view of the electronic module shown in FIG. 9(a).

FIG. 10(a) is a longitudinal sectional view of an electronic module that can be used in a fifth embodiment of the present invention. FIG. 10(b) is a plan view of the electronic module shown in FIG. 10(a).

FIG. 11 is a plan view showing a lead frame which can be used in a sixth embodiment of the present invention, and virtually shows a planned position where the second substrate is to be arranged and a planned cutting line.

FIG. 12 is a plan view showing an aspect in which a first positioning member is formed by cutting and bending the lead frame shown in FIG. 11.

FIG. 13(a) is a longitudinal sectional view showing a positioning part composed of the lead frame, which can be used in the sixth embodiment of the present invention. FIG. 13(b) is a longitudinal sectional view showing another aspect of the positioning part composed of the lead frame, which can be used in the sixth embodiment of the present invention.

FIG. 14 is a plan view showing a first connection body which can be used in a seventh embodiment of the present invention.

FIG. 15 is a longitudinal sectional view showing a second connection body which can be used in an eighth embodiment of the present invention.

### DESCRIPTION OF EMBODIMENTS

### First Embodiment

### «Configuration»

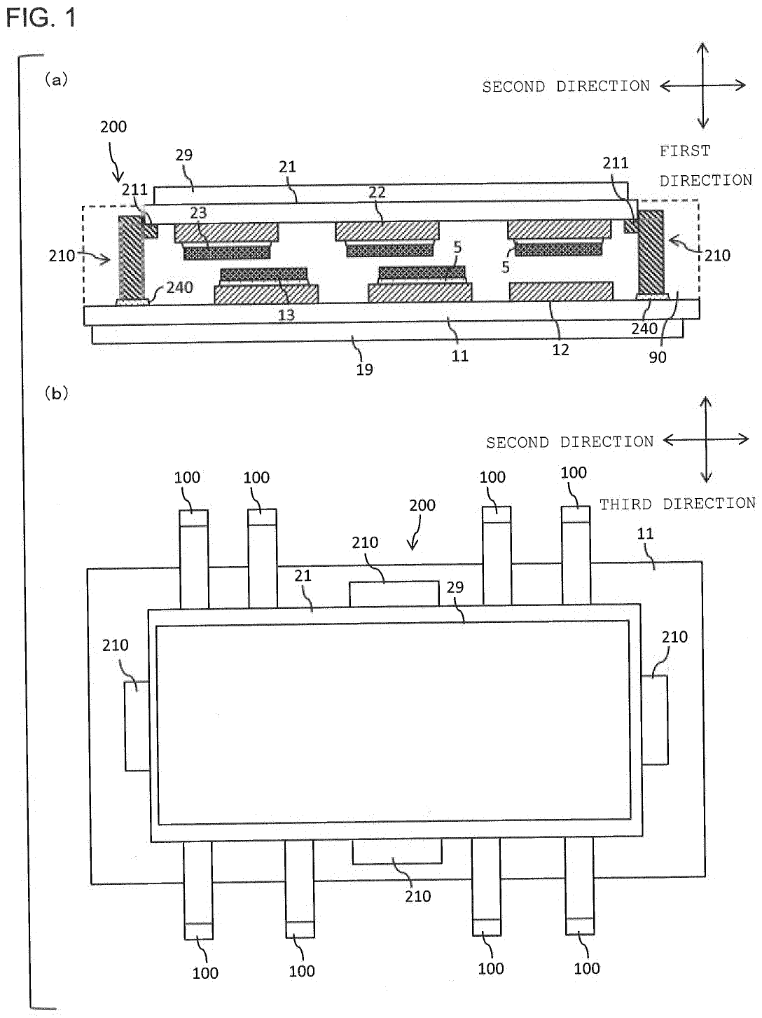

In the present embodiment, “one side” means the upper side of FIG. 1(a), “the other side” means the lower side of FIG. 1(a). The vertical direction in FIG. 1 (a) is called a “first direction”, the left and right direction is called a “second direction”, and the front and back direction of the page surface is called a “third direction”. The in-plane direction including the second direction and the third direction is called a “surface direction”, and when viewed from one side, the view is called a “plan view”.

The electronic module according to the present embodiment may have a first electronic unit and a second electronic unit.

As shown in FIG. 1(a), the first electronic unit may have a first substrate 11, a plurality of first conductive layers 12 provided on one side of the first substrate 11, and a first electronic element 13 provided on one side of the first conductive layers 12. The first electronic element 13 may be a switching device or a control device. If the first electronic element 13 is a switching device, the first electronic element 13 may be a MOSFET, an IGBT or the like. Each of the first electronic element 13 and the second electronic element 23 described below may be formed of a semiconductor device. The semiconductor material may be silicon, silicon carbide, gallium nitride, or the like. The other side surface of the first electronic element 13 may be connected to the first conductive layer 12 via a conductive adhesive 5 such as solder.

As shown in FIG. 1(a), the second electronic unit may have a second substrate 21, a plurality of second conductive layers 22 provided on the other side of the second substrate 21, and a second electronic element 23 provided on the other side of the second conductive layer 22. The surface on one side of the second electronic element 23 may be connected to the second conductive layer 22 via the conductive adhesive 5 such as solder.

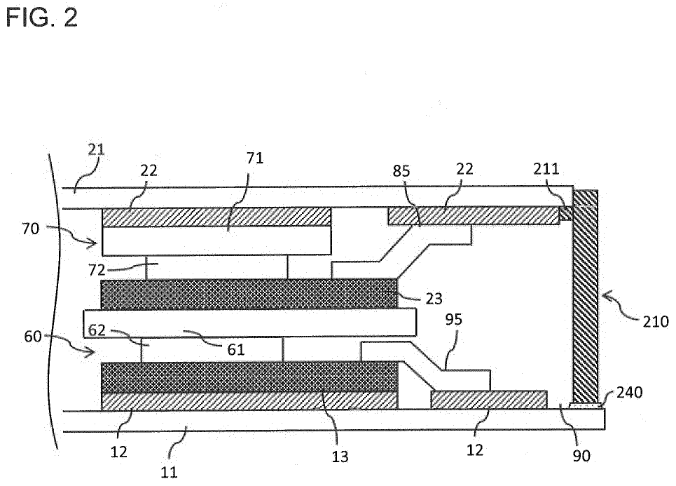

As shown in FIG. 2, a first connection body 60 may be provided on one side of the first electronic element 13. The first connection body 60 may be connected to the surface of the one side of the first electronic element 13 via the conductive adhesive 5 (not shown in FIG. 2) such as solder. In the aspect shown in FIG. 2, the first connection body 60 is provided between the first electronic element 13 and the second electronic element 23, which causes the first electronic element 13 and the second electronic element 23 to be electrically connected by the first connection body 60.

As shown in FIG. 2, a second connection body 70 may be provided on the other side of the second conductive layer 22. The second connection body 70 may be connected to the surface of the one side of the second electronic element 23 and the other side of the second conductive layer 22 via the conductive adhesive 5 such as solder.

It should be noted that the first electronic element 13 is fixed to the first substrate 11 by being connected to the first conductive layer 12 provided on the first substrate 11 via the conductive adhesive 5. Similarly, the second electronic element 23 is fixed to the second electronic element 23 by being connected to the second conductive layer 22 provided on the second substrate 21 via the conductive adhesive 5.

The second electronic element 23 may be a switching device or a control device. When the second electronic element 23 is a switching device, the second electronic element 23 may be a MOSFET, an IGBT, or the like.

As shown in FIG. 2, the first connection body 60 may have a first head part 61 and a first pillar part 62 extending from the first head part 61 to the other side. The second connection body 70 may have a second head part 71 and a second pillar part 72 extending from the second head part 71 to the other side. The first connection body 60 has a substantially T-shaped cross section and the second connection body 70 may also have a substantially T-shaped cross section.

As the first substrate 11 and the second substrate 21, a ceramic substrate, an insulating resin layer, or the like can be adopted. As the conductive adhesive 5, in addition to solder, a material containing Ag or Cu as a main component can be used. As the material of the first connection body 60 and the second connection body 70, a metal such as Cu can be used. As the substrates 11 and 12 provided with the conductive layers 12 and 22, a metal substrate formed with a circuit pattern can be used. As the substrates 11, 21, for example, a metal substrate formed with a circuit pattern can be used. In this case, the substrates 11, 21 also serve as the conductive layers 12 and 22.

As shown in FIG. 1(a), the electronic module may have a sealing part 90 including a sealing resin or the like for sealing the first electronic element 13, the second electronic element 23, the first connection body 60, the second connection body 70, the first conductive layer 12, the second conductive layer 22, and the like as described above. On the other side of the first substrate 11, a first heat sink 19 formed of a copper plate or the like may be provided. A second heat sink 29 formed of a copper plate or the like may be provided on one side of the second substrate 21.

The first conductive layer 12 or the second conductive layer 22 may be connected to a terminal part 100 and the distal end side of the terminal part 100 may be exposed to the outside of the sealing part 90 to be connectable to the external device. The terminal part 100 shown in FIG. 1(b) has an aspect in which the terminal part 100 bends to one side, and has an aspect in which a tip thereof is extending to the front side of the page of FIG. 1(b).

A positioning part 200 extending from the first substrate 11 to one side and abutting the circumferential part of the second substrate 21 may be provided. The positioning part 200 may have a plurality of first positioning members 210. In the present embodiment, the following description will be made using the aspect in which four first positioning members 210 are provided. However, the present invention is not limited thereto, and two, three, or five or more first positioning members 210 may be provided.

Each of the first substrate 11 and the second substrate 21 may have a substantially rectangular shape. As shown in FIG. 1(b), the first positioning members 210 may be provided so as to correspond to each side (each of four sides). The present embodiment is not limited to this aspect, and the first positioning members 210 may be provided so as to correspond to two sides or three sides, or may be provided with two or more first positioning members 210 for one side (e.g., long side).

The first positioning member 210 may be provided at the central part of each side. In the present embodiment, the “central part” means the central region when divided into five equal parts along the side. In the present embodiment, the “substantially rectangular shape” means a quadrangle having two pairs of sides opposed to each other and, for example, the corner parts may be rounded. It should be noted that a first guide member 210 may not necessarily be provided at the central part of each side of the second substrate 21, and only some of the plural first positioning members 210 may be provided at the central part of the side of the second substrate 21. The remaining of the plural first positioning members 210 may be provided on the corner sides other than at the central part of the side of the second substrate 21.

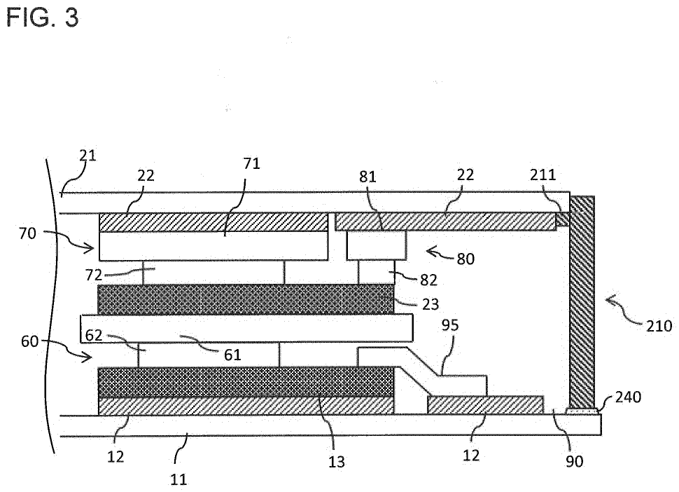

As shown in FIG. 1(a), each of the first positioning members 210 of the positioning part 200 may have a first protrusion part 211 protruding inwardly. The first protrusion part 211 may come into contact with the other surface of the second substrate 21. As shown in FIG. 2 and FIG. 3, the first protrusion part 211 may abut the circumferential part of the second conductive layer 22.

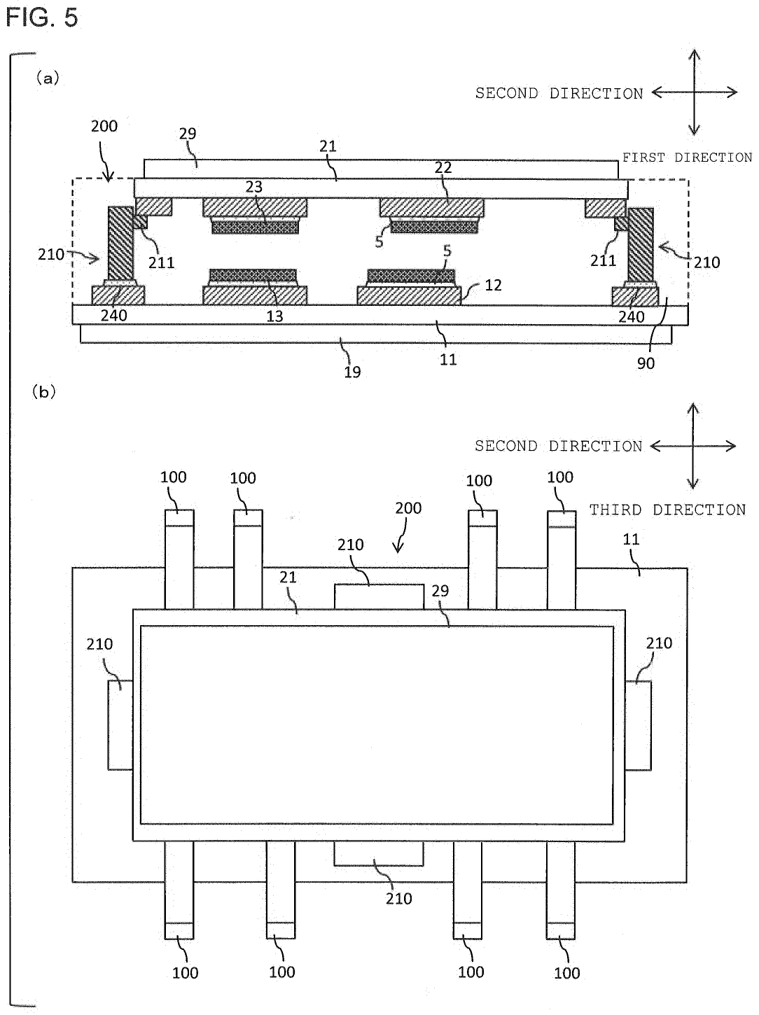

The first protrusion part 211 does not abut against the other side of the second substrate 21 and, as shown in FIG. 5, the first protrusion part 211 may come into contact with the other side of the second conductive layer 22.

It should be noted that the first protrusion part 211 need not be provided in each of the first positioning members 210. The first protrusion part 211 may be provided only in some of the plural first positioning members 210, and the first positioning member 210 may not be provided in the remaining of the plural first positioning members 210. As an example, the first protrusion part 211 may be provided in two first positioning members 210 for supporting a pair of opposing sides (for example, long sides) of the second substrate 21, and the first protrusion part 211 may not be provided for the first positioning member 210 supporting another pair of sides (for example, the short side).

Unlike the aspect as described above, the first protrusion part 211 may not be provided. In this case, the positioning part 200 only performs positioning of second substrate 21 in the surface direction with respect to first substrate 11.

The first positioning member 210 of the positioning part 200 may be fixed to the first substrate 11 using a bonding material 240. The melting point of the bonding material 240 may be higher than the melting point of the conductive adhesive 5.

The first positioning member 210 of the positioning part 200 may be bonded and fixed to the surface of the one side of the first substrate 11 (the upper surface of FIG. 1) by the bonding material 240. When this aspect is adopted, the size of the surface direction of the first substrate 11 may be larger than the surface direction of the second substrate 21. The first positioning member 210 may be bonded to the first conductive layer 12 with the bonding material 240 (see FIG. 5). In this case also, the first positioning member 210 is bonded to one side of the first substrate 11.

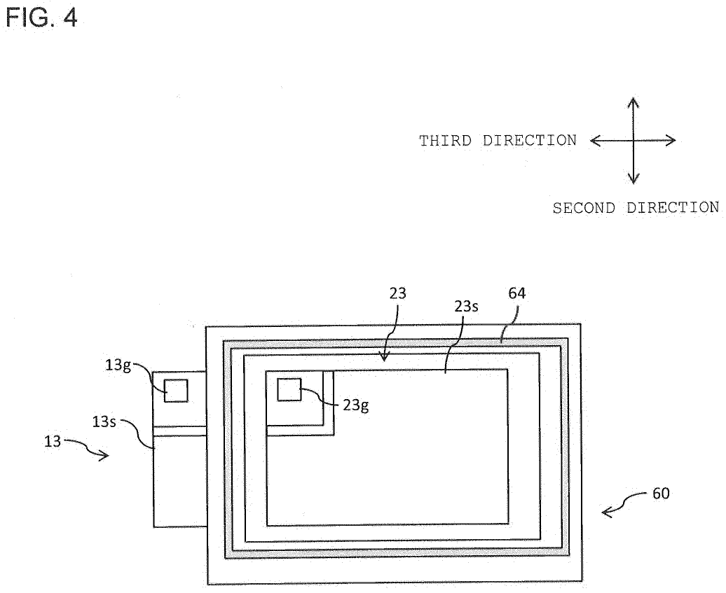

As shown in FIG. 4, a first groove part 64 may be provided on the surface on one side of the first head part 61. Although the first groove part 64 is provided on the outside of the periphery of the first pillar part 62 in the surface direction, the first groove part 64 may be provided on a part of the outside of the periphery of the first pillar part 62 or may be provided all over the outside of the periphery. The conductive adhesive 5 such as solder may be provided on a surface at the one side of the first head part 61 and on the inside the periphery of the first groove part 64, and a second electronic element 23 may be provided via the conductive adhesive 5.

As shown in FIG. 2, a connector 85 connected to a terminal, such as a second gate terminal 23g, to be described later, of the second electronic element 23, may be used. The present embodiment is not limited to this aspect, and a third connection body 80 as shown in FIG. 3 may be used. The third connection body 80 may have a third head part 81 and a third pillar part 82 extending from the third head part 81 to the other side. The third connection body 80 may be connected to the other surface of the second conductive layer 22 and to one surface of the second electronic element 23 via the conductive adhesive 5 (not shown in FIG. 3) such as solder.

As shown in FIG. 4, in the plan view, the first electronic element 13 may have an aspect in which it is exposed from the first head part 61. In the case where the first electronic element 13 is a switching device such as a MOSFET, a first gate terminal 13g or the like may be provided in a part exposed from the first head part 61 in plan view. Similarly, when the second electronic element 23 is a switching device such as a MOSFET, a second gate terminal 23g or the like may be provided on the surface on one side. The first electronic element 13 shown in FIG. 4 has the first gate terminal 13g and a first source terminal 13s on one side, and the second electronic element 23 has a second gate terminal 23g and a second source terminal 23s on one side. In this case, the second connection body 70 may be connected to the second source terminal 23s of the second electronic element 23 via the conductive adhesive 5, and the connector 85 is connected to the second gate terminal 23g of the second electronic element 23 via the conductive adhesive 5. The first connection body 60 may connect the first source terminal 13s of the first electronic element 13 and the second drain terminal provided on the other side of the second electronic element 23 via the conductive adhesive 5. A first drain terminal provided on the other side of the first electronic element 13 may be connected to the first conductive layer 12 via the conductive adhesive 5. The first gate terminal 13g of the first electronic element 13 may be connected to the connector 95 (see FIG. 2 and FIG. 3) via the conductive adhesive 5, and the connector 95 may be connected to the first conductive layer 12 via the conductive adhesive 5.

In the case where only one of the first electronic element 13 and the second electronic element 23 is a switching device, it may be possible to use a low heat generation control device as the second electronic element 23 mounted on the first connection body 60 and a switching device as the first electronic element 13. Conversely, it may be also possible to use a switching device as the second electronic element 23 mounted on the first connection body 60 and a low heat generation control device as the first electronic element 13.

Bonding of the terminal part 100 and the conductive layers 12, 22 is not limited to the aspect utilizing the conductive adhesive 5 such as solder. Alternatively, laser welding or ultrasonic bonding may be used.

### «Actions and Effects»

Next, examples of actions and effects according to the present embodiment including the above configuration will be described. Any aspect described in “actions and effects” can be adopted in the above configuration.

As shown in FIG. 1(a) and others, when adopting an aspect in which a positioning part 200, which extends from the one side of the first substrate 11 to one side and abuts against the circumferential part of the second substrate 21, is provided, the second substrate 21 can be positioned in the surface direction with respect to the first substrate 11 without using jigs. Hence, it is advantageous in that the first substrate 11 and the second substrate 21 can be kept in parallel. That is, by positioning the second substrate 21 in the surface direction with respect to the first substrate 11, the second substrate 21 can be prevented from deviating in the surface direction with respect to the first substrate 11. As a result, the second substrate 21 can be prevented from tilting in the first direction with respect to the first substrate 11.

In view of keeping the first substrate 11 and the second substrate 21 in parallel in the conventional aspect, it is necessary to make the jigs and the substrates 11, 21 have almost the same sizes in the surface direction. However, in the case in which the jigs are enlarged in such a manner, the jigs themselves may elongate due to the application of heat, for example, when reflowing the conductive adhesive 5 such as solder. Especially, when the jigs themselves are elongated in the case where the substrates 11, 21 are also positioned in the first direction, the substrates 11, 21 are also caused to be warped or distorted. In this regard, when the positioning part 200 as in the present embodiment is adopted, due to the size of the positioning part 200 itself being not so large, the amount of extension will not be so large even if heat is added. Therefore, it is possible to prevent the substrates 11, 21 from being warped or distorted.

In addition, in the case where the jigs position the substrates 11, 21 also in the first direction, if the dimensional tolerance of the jigs is set larger to prevent warpage and distortion of the substrates 11, 21, the first substrate 11 and the second substrate 21 are difficult to be kept in parallel with each other. In this regard, when adopting the positioning part 200 as in the present embodiment, it is advantageous in that the substrates 11, 21 can be prevented from being warped or distorted while keeping the first substrate 11 and the second substrate 21 in parallel. These effects are particularly large when the size of the surface direction of the substrates 11, 21 is increased. Thus, in aspects where multiple electronic elements 13, 23 are provided in the surface direction, the aspect of the present embodiment is particularly advantageous.

In the case of adopting an aspect in which the positioning part 200 has a plurality of first positioning members 210, the plurality of first positioning members 210 can be used to enable more accurate positioning.

When the second substrate 21 has a substantially rectangular shape and the first positioning member 210 is provided so as to correspond to each side (each of four sides), the first positioning member 210 can perform positioning at each side of the second substrate 21. Therefore, the second substrate 21 can be reliably prevented from deviating in the surface direction with respect to the first substrate 11.

In the case where the first positioning member 210 is provided at the central part of each side, it is advantageous in that the second substrate 21 can be positioned with respect to the first substrate 11 in a well-balanced manner.

In the case where the first protrusion part 211 is provided in the first positioning member 210, positioning of the second substrate 21 in the first direction can also be performed, so that the distance between the second substrate 21 and the first substrate 11 can be set to a certain value or more. The fact that the positioning in the first direction can be performed in this manner makes it possible to increase the thickness of the conductive adhesive 5 such as solder used for connecting the electronic elements 13, 23 to a certain value or more, which is advantageous in that reliability can be increased. In particular, when the first protrusion part 211 is provided in each of the first positioning members 210, it is more advantageous in that the positioning of the second substrate 21 in the first direction can also be performed more reliably. As described above, the first protrusion part 211 may contact the surface of the other side of the second substrate 21 as shown in FIG. 1(a) or others, or on the second conductive layer 22 on the surface of the other side or as shown in FIG. 5 (a).

When the size of the surface direction of the substrate 11, 21 is increased, the substrate is easily warped or distorted. In this respect, if the first protrusion part 211 as described above is provided, warpage and distortion of the substrate can be prevented, which is advantageous.

As shown in FIGS. 2 and 3, when the first protrusion part 211 abuts against the other surface of the second substrate 21 and contacts the circumferential part of the second conductive layer 22, it is advantageous in that the first protrusion part 211 can also perform positioning of the second substrate 21 in the surface direction.

According to the aspect in which the first positioning member 210 is fixed to the first substrate 11 using the bonding material 240, it is advantageous in that it is only necessary to attach the first positioning member 210 to the first substrate 11 that is conventionally used. In the case where the aspect in which the melting point of the bonding material 240 is higher than the melting point of the conductive adhesive 5 such as solder used for connection in the electronic module is adopted, it is possible to prevent the fixation of the first positioning member 210 to the first substrate 11 from loosening even when utilizing the step of remelting the conductive adhesive 5. Therefore, when the conductive adhesive 5 is remelted, it is possible to prevent the positions of the second substrate 21 and the first substrate 11 from deviating. In the case of fixing the first positioning member 210 to the first substrate 11, metal nanoparticles may be used in addition to high melting point solder, or ultrasonic bonding, laser bonding or the like may be used.

When the positioning part 200 is fixed to the surface of the one side of the first substrate 11, it is only necessary to fix the positioning part 200 on the surface of the one side of the first substrate 11, which is advantageous in that it facilitates manufacturing. It should be noted that the positioning part 200 need not be fixed to a surface of the one side of the first substrate 11, and the positioning part 200 may be fixed to a side surface of the first substrate 11 via the bonding material 240, for example.

In addition, when adopting the first connection body 60 as shown in FIG. 2 and FIG. 3, the distance between the first substrate 11 and the second substrate 23 on the inside of the peripheries of the substrates 11, 21 can be kept above a certain value or more by the first connection body 60. Therefore, it is advantageous in that it is possible to more reliably prevent the substrates 11, 21 from being warped or distorted even when large substrates 11, 21 are employed in the surface direction.

Similarly, even when the second connection body 70 is adopted, the distance between the first substrate 11 and the second substrate 23 on the inside the periphery of the substrates 11, 21 can be kept a certain value or more. Therefore, it is advantageous in that it is possible to more reliably prevent the substrates 11, 21 from being warped or distorted even when large substrates 11, 21 are employed in the surface direction.

FIG. 2 and FIG. 3 shows an aspect in which the first connection body 60 and the second connection body 70 are used, but the first connection body 60 and the second connection body 70 may not be provided (see FIG. 1(a) and FIG. 5(a)).

### Second Embodiment

Next, a second embodiment of the present invention will be described.

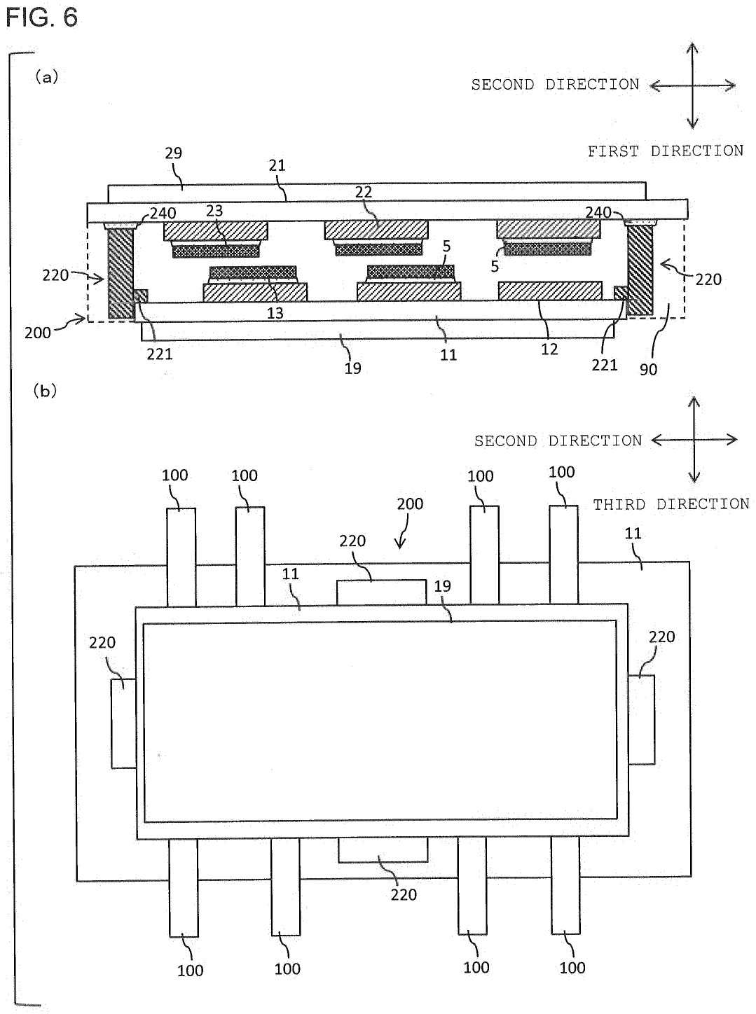

In the first embodiment, the positioning part 200 has an aspect in which it extends from the first substrate 11 to one side and abuts against the circumferential part of the second substrate 21. However, in the present embodiment, as shown in FIG. 6, the positioning part 200 has an aspect in which it extends from the second substrate 21 to the other side and abuts against the circumferential part of the first substrate 11. For other configurations, the second embodiment is similar to the first embodiment, any aspect described in the first embodiment can be adopted. The same reference numerals will be used to denote the members described in the first embodiment.

As described above, in the present embodiment, any aspect described in the first embodiment can be adopted and the positioning part 200 may have a plurality of second positioning members 220. The second positioning member 220 may be provided with a second protrusion part 221. The second protrusion part 221 may be in contact with the surface of one side of the first substrate 11. In addition, the second protrusion part 221 may be in contact with the circumferential part of the first conductive layer 12.

The second positioning member 220 may be fixed to the other surface of the second substrate 21. When this aspect is adopted, the size of the surface direction of the second substrate 21 may be larger than the surface direction of the first substrate 11.

According to the present embodiment, it is possible to position the first substrate 11 with respect to the second substrate 21, using the second positioning member 220 of the positioning part 200 extending from the second substrate 21 toward the first substrate 11. Therefore, for example, it is conceivable to adopt the aspect of the present embodiment, rather than the aspect shown in the first embodiment, when it is necessary in terms of the design or the manufacturing process.

### Third Embodiment

Next, a third embodiment of the present invention will be described.

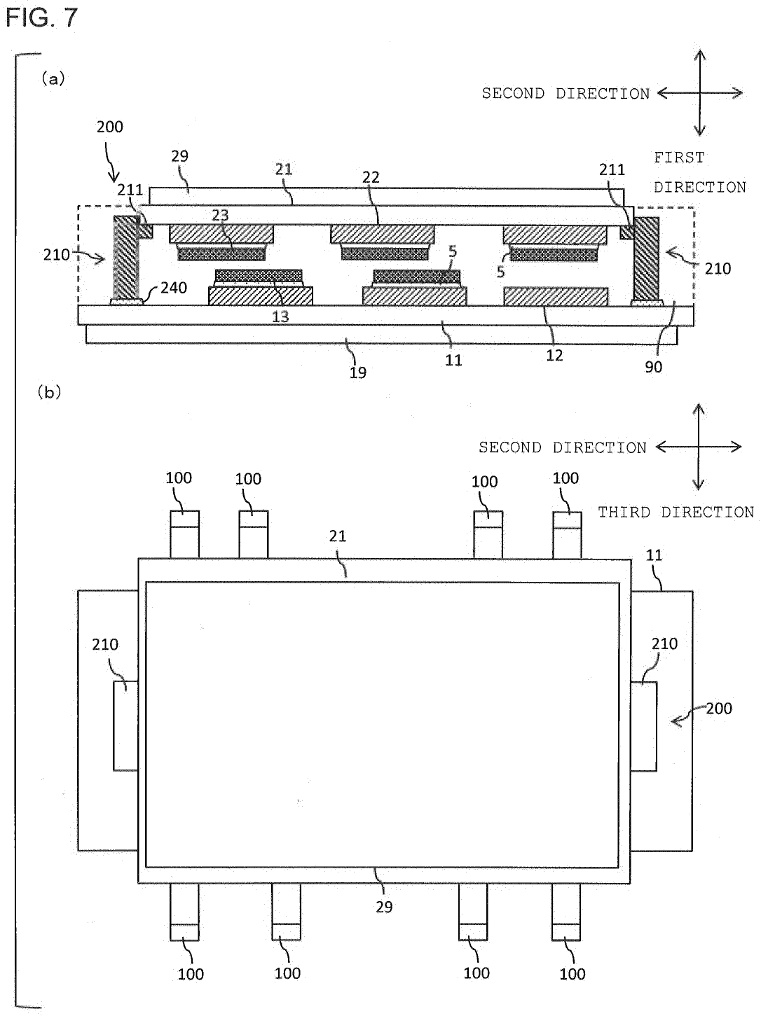

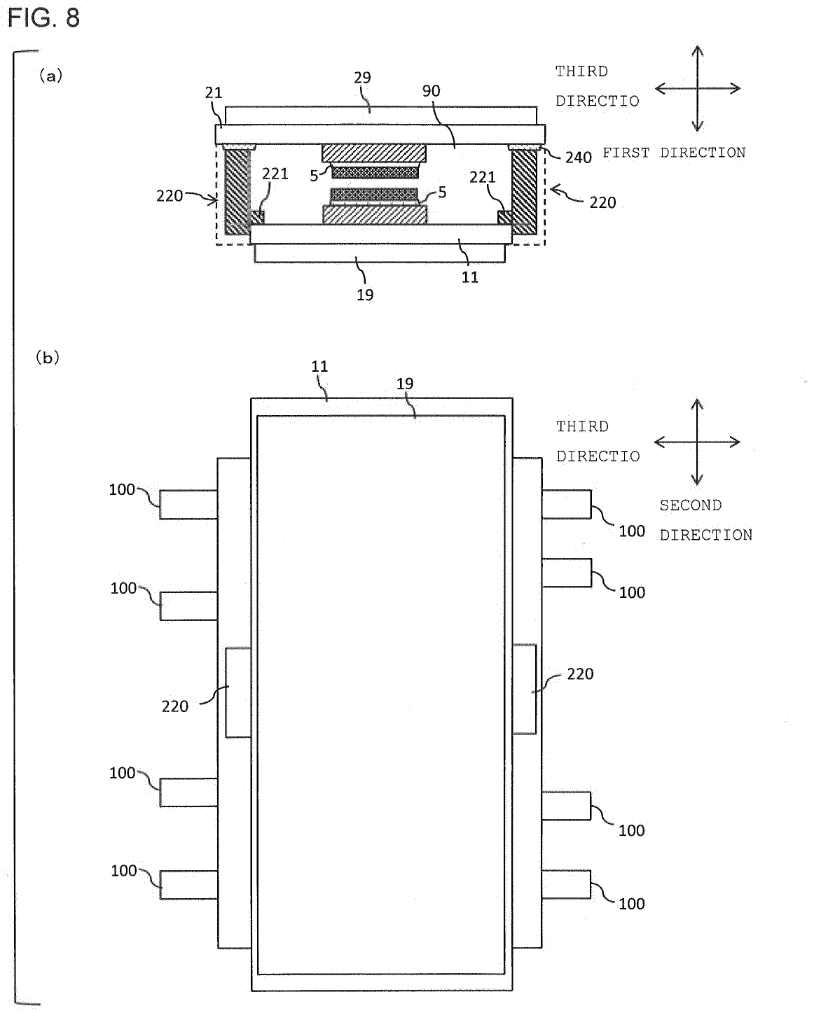

As shown in FIG. 7 and FIG. 8, the present embodiment has an aspect using both of a first positioning member 210 extending from the first substrate 11 to one side and abutting a circumferential part of the second substrate 21 and a second positioning member 220 extending from the second substrate 21 to the other side and abutting the circumferential part of the first substrate 11. For other configurations, the third embodiment is similar to each of the above embodiments, and any aspect described in the above embodiments can be adopted. The same reference numerals will be used to denote the members described in the above embodiments.

As described above, also in the present embodiment, any aspect described in the first embodiment and the second embodiment can be adopted, and even in the present embodiment, a first protrusion part 211 may be provided in the first positioning member 210, and a second protrusion part 221 may be provided in the second positioning member 220.

The first protrusion part 211 provided on the first positioning member 210 may be in contact with the other side surface of the second substrate 21. In addition, the first protrusion part 211 may abut a circumferential part of the second conductive layer 22. The second protrusion part 221 provided on the second positioning member 220 may be in contact with the surface on one side of the first substrate 11. In addition, the second protrusion part 221 may be in contact with the circumferential part of the first conductive layer 12.

As an example of the present embodiment, as shown in FIG. 7 and FIG. 8, two first positioning members 210 and two second positioning members 220 may be used. In this case, a pair of first positioning members 210 may be provided on opposing sides of the first substrate 11, and a pair of second positioning members 220 may be provided on opposing sides of the second substrate 21. However, the present invention is not limited thereto. For example, two first positioning members 210 may be provided on adjacent sides of the first substrate 11, and two second positioning members 220 may be provided on adjacent sides of the second substrate 21.

The first positioning member 210 may be fixed to one side surface of the first substrate 11, and the second positioning member 220 may be fixed to the other surface of the second substrate 21. In this aspect, if a pair of first positioning members 210 are provided on opposite sides of the first substrate 11 and a pair of second positioning members 220 are provided on opposite sides of the second substrate 21, as shown in FIG. 7, the length of the second substrate 21 may be shorter than the length of the first substrate 11 in the surface direction (second direction) in which the two first positioning members 210 are provided, and as shown in FIG. 8, the length of the first substrate 11 may be shorter than the length of the second substrate 21 in the surface direction (the third direction) in which the two second positioning members 220 are provided.

Also, when two first positioning members 210 are provided on adjacent sides and two second positioning members 220 are provided on adjacent sides, the first substrate 11 and the second substrate 21 may be arranged to be inclined in the oblique direction (the second direction (the direction between the first direction and the third direction). In this case, the two first positioning members 210 abut on two adjacent sides of the second substrate 21, and the two second positioning members 220 abut on two adjacent sides of the first substrate 11.

According to the present embodiment, each of the first positioning member 210 and the second positioning member 220 can be used to position the relative position between the first substrate 11 and the second substrate 21.

### Fourth Embodiment

Next, a fourth embodiment of the present invention will be described.

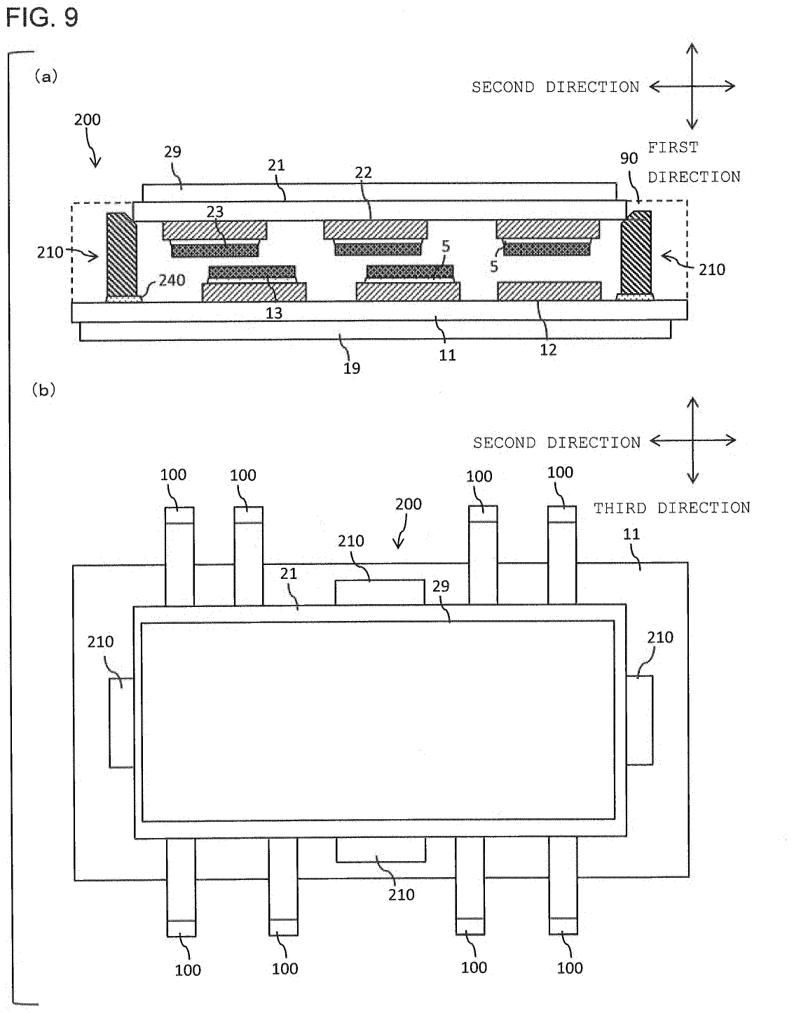

In each of the above embodiments, the shapes of the tip of the positioning members 210, 220 have not been particularly mentioned, but, in the present embodiment, as shown in FIG. 9, the tip of the positioning members 210, 220 of the positioning part 200 has a tapered shape. In the present embodiment, any aspect described in the above embodiments can be adopted. The same reference numerals will be used to denote the members described in the above embodiments.

By adopting the aspect in which the tip of the positioning member 210, 220 of the positioning part 200 has a tapered shape as in the present embodiment, positioning in the surface direction can be performed more easily. More specifically, in the aspect like the first embodiment, in the case of adopting the aspect in which the tip of the first positioning member 210 has a tapered shape, when positioning the second substrate 21 with respect to the first substrate 11, just by bringing the second substrate 21 to the first substrate 11 along the first direction, the second substrate 21 is moved along the tip of the first positioning member 210 in the surface direction so that positioning can be performed. In the aspect like the second embodiment, in the case of adopting the aspect in which the tip of the second positioning member 220, when positioning the first substrate 11 with respect to the second substrate 21, by merely bringing the first substrate 11 closer to the second substrate 21 along the first direction, the first substrate 11 is moved along the tip of the second positioning member 220 in the direction of the surface so that positioning can be performed. This also applies to the case where the aspect like the third embodiment is adopted. In the present embodiment, as shown in FIG. 9, the interval between the second positioning members 220 provided on the opposing sides is smaller than the length in the width direction of the substrates 11, 21 corresponding to the opposing sides. By adopting such an aspect, the tapered part of the positioning member 210, 220 comes into contact with the circumferential part of the substrates 11, 21, so that positioning in the surface direction and first direction becomes possible.

### Fifth Embodiment

Next, a fifth embodiment of the present invention will be described.

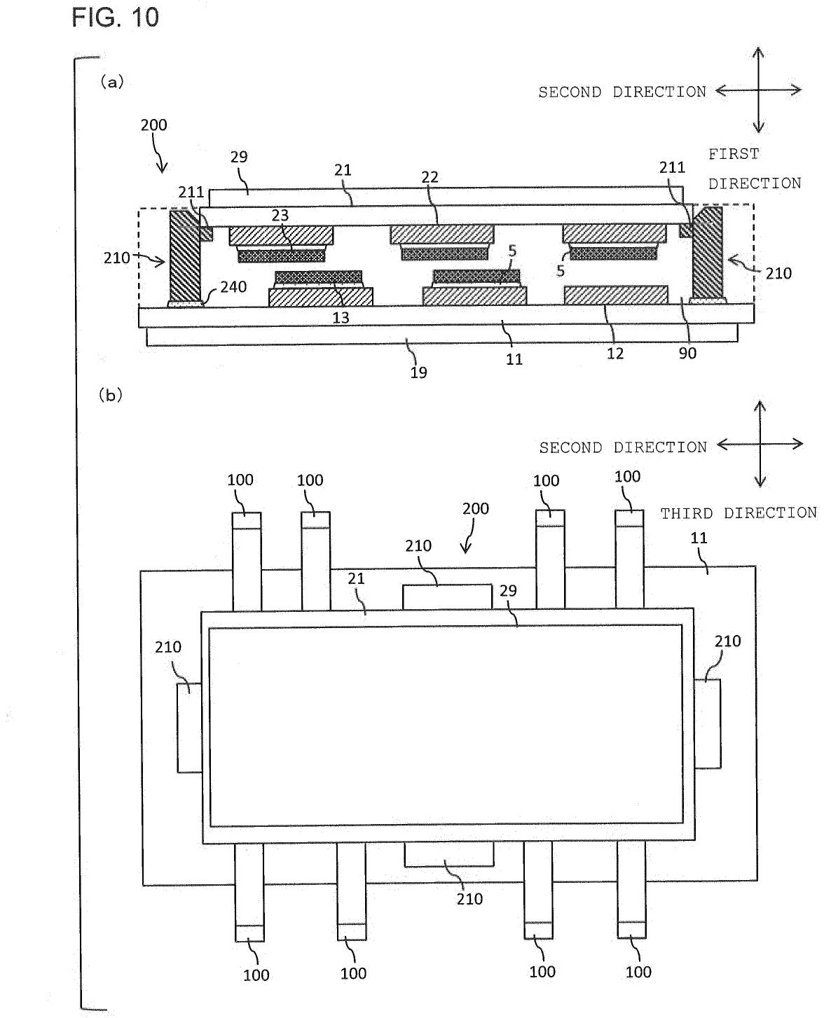

As shown in FIG. 10, the present embodiment has an aspect in which the distance between the positioning members 210, 220 provided on the opposing sides is equal to or larger than the substrate 11, 21, and the protrusion parts 211, 221 are provided on the positioning member 210, 220. For other configurations, the fifth embodiment is similar to the fourth embodiments. In the present embodiment, any aspect described in the above embodiments can be adopted. The same reference numerals will be used to denote the members described in the above embodiments.

According to the present embodiment, the substrates 11, 21 are guided by the tapered part of the positioning members 210, 220 and can be finally positioned in the surface direction and first direction of the substrates 11, 21 by the protrusion parts 211, 221. Specifically, in the aspect like the first embodiment, in the case where the tip of the first positioning member 210 has a tapered shape and the first protrusion part 211 is provided, when positioning the second substrate 21 with respect to the first substrate 11, just by making the second substrate 21 close to the first substrate 11 along the first direction, the second substrate 21 is moved along the tip of the first positioning member 210 in the direction of the surface, and the surface of the second substrate 21 on the other side is supported by the first protrusion part 211, so that the second substrate 21 can be positioned with respect to the first substrate 11 in the surface direction and the first direction. In the aspect like the second embodiment, in the case where the tip of the second positioning member 220 has a tapered shape and the second protrusion part 221 is provided, when positioning the first substrate 11 with respect to the second substrate 21, just by bringing the first substrate 11 closer to the second substrate 21 along the first direction, the first substrate 11 moves along the tip of the second positioning member 220 in the surface direction, and the surface of one side of the first substrate 11 is supported by the second protrusion part 221, and it is possible to position the first substrate 11 in the surface direction and the first direction with respect to the second substrate 21. This is also applicable to the case where the aspect like the third embodiment is adopted.

### Sixth Embodiment

Next, a sixth embodiment of the present invention will be described.

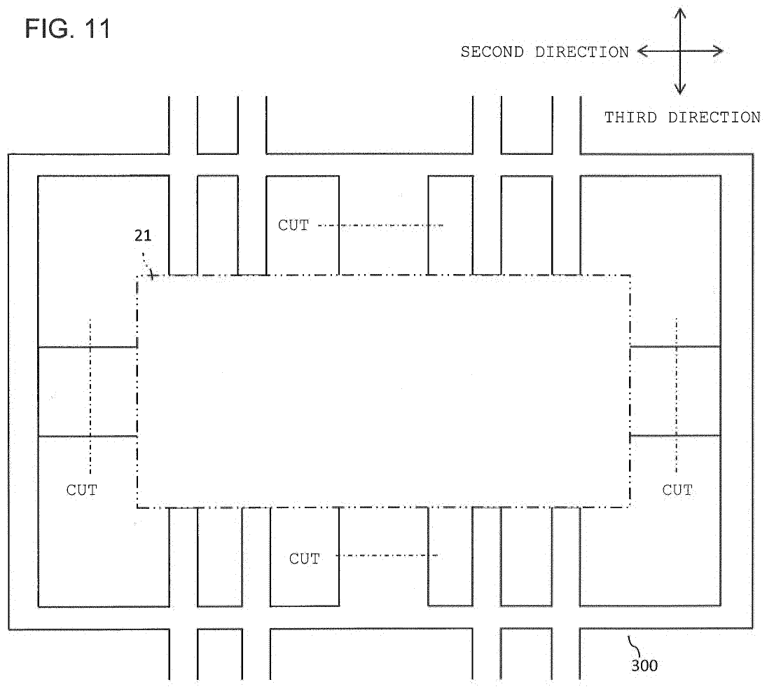

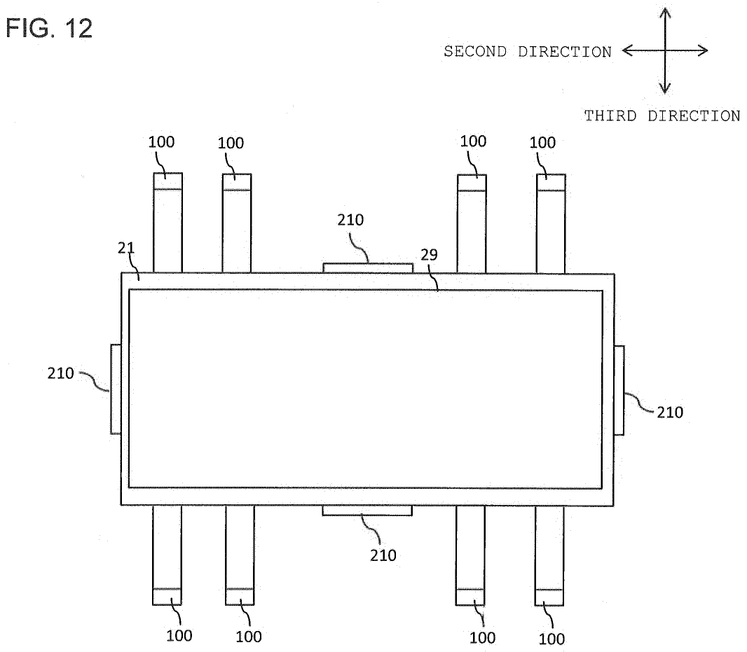

In each of the above embodiments, the positioning part 200 has an aspect in which it is fixed to the substrate 11, 21 by the bonding material 240. However, in the present embodiment, the positioning part 200 formed of a lead frame 300 for forming the terminal part 100 and the like (see FIG. 11 and FIG. 12). In the present embodiment, any aspect described in each of the above embodiments can be adopted. The same reference numerals will be used to denote the members described in the above embodiments.

In the present embodiment, the positioning part 200 is formed by cutting the lead frame 300 at an appropriate place and then folding it. More specifically, the positioning part 200 is formed by cutting the lead frame 300 (see FIG. 11) at the intended cutting position and bending it to one side or the other side (see FIG. 12).

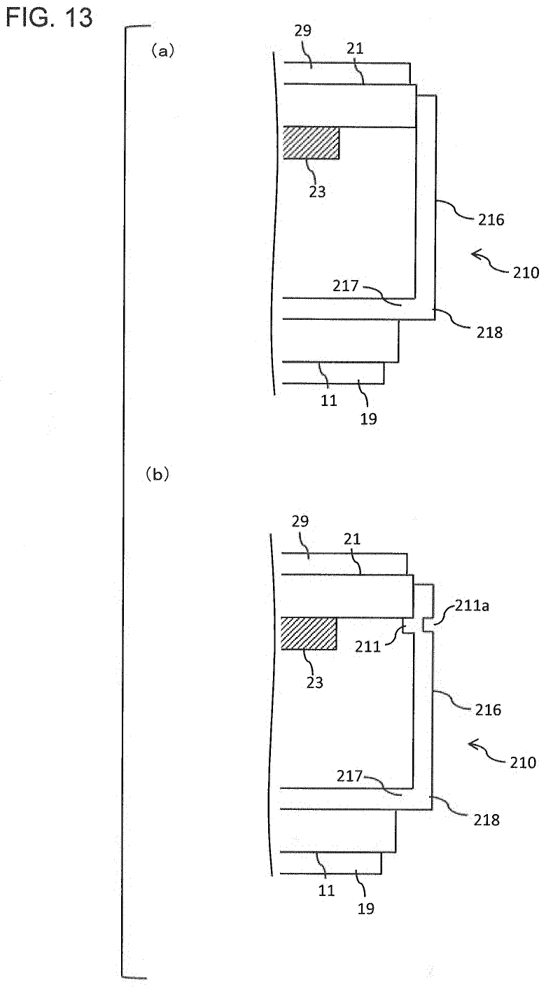

The positioning part 200 according to the present embodiment may have a lead frame proximal end part extending in the surface direction and a lead frame extension part provided on the lead frame proximal end part via a lead frame bend part and extending to one side or the other side. In the aspect shown in FIG. 13, the positioning part 200 according to the present embodiment has a first lead frame proximal end part 217 extending in the surface direction and a first lead frame extension part 216 provided on the first lead frame proximal end part 217 via the lead frame bent part 218 and extending to one side.

Even in the present embodiment, if the protrusion parts 211, 221 are provided, the lead frame 300 may be struck or pressed on the side opposite to the place where the protrusion parts 211, 221 are provided. By striking or pressing the lead frame 300 in this way, the protrusion parts 211, 221 are formed. In this case, as shown in FIG. 13(b), a recess part 211a corresponding to the protrusion part 211 is formed.

In FIGS. 11 to 13, the first guide member 210 is described using the aspect formed by the lead frame 300, but as described above, any aspect described in each of the above embodiments can be adopted. The second guide member 220 may be formed by the lead frame 300.

According to the present embodiment, the positioning part 200 can be formed using the lead frame 300, which is advantageous in that there is no need to use the bonding material 240.

### Seventh Embodiment

Next, a seventh embodiment of the present invention will be described.

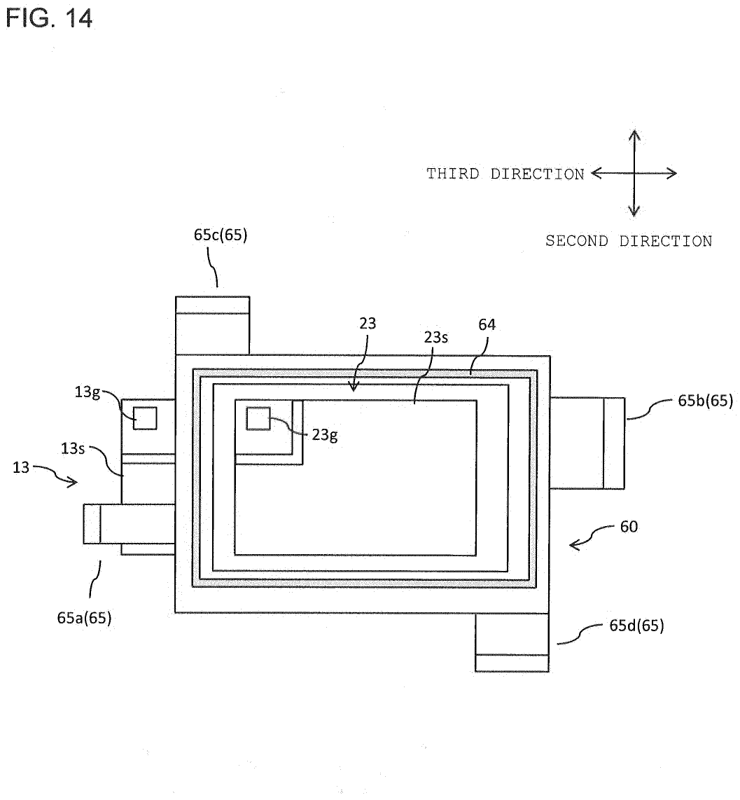

In each of the above embodiments, the first connection body 60 having a substantially T-shaped cross section was used. However, as shown in FIG. 14, the first connection body 60 of the present embodiment has four support parts 65 (65a to 65d) extending from the first head part 61 to the other side. The support body 65 abuts the first conductive layer 12 or the first substrate 11. Even in the present embodiment, any aspect described in each of the above embodiments can be adopted. The same reference numerals will be used to denote the members described in the above embodiments.

The present embodiment will be described using the aspect in which four support parts 65 are used, but it is not limited thereto, and one, two, three, or five or more support parts 65 may be used.

In the case where the support part 65 extending from the first head part 61 is provided as in the present embodiment, the first connection body 60 can be prevented from being inclined due to the weight of the second electronic element 23 when the second electronic element 23 is mounted or after the second electronic element 23 is mounted. In this manner, the support part 65 abuts against the first substrate 11 or the first conductive layer 12, so that the heat radiation performance can be enhanced. In particular, when the support part 65 abuts the first conductive layer 12, it is advantageous in that the heat radiation effect can be further enhanced.

By using the first connection body 60 having a plurality of support parts 65 as in the present embodiment, positioning in the first direction inside the peripheries of the substrates 11, 21 can be more reliably performed. In particular, in the case of adopting the protrusion parts 211, 221 and adopting the first connection body 60 having a plurality of support parts 65, positioning can be performed in the first direction in the circumferential parts of the substrates 11, 21 by the protrusion parts 211, 221 while positioning is performed in the first direction inside the peripheries of the substrates 11, 21 by the first connection body 60 having a plurality of support parts 65. Therefore, it is advantageous in that it is possible to more reliably prevent the substrates 11, 21 from being warped or distorted even when the large substrates 11, 21 are employed in the surface direction.

As in the fourth embodiment, even when adopting an aspect in which the tip of the positioning members 210, 220 is tapered and the distance between the second positioning members 220 provided on the opposite sides is smaller than that of the substrates 11, 21, positioning can be performed in the first direction inside the peripheries of the substrates 11, 21 by the first connection body 60 while positioning is performed in the first direction in the circumferential parts of the substrates 11, 21 by the tip of the positioning members 210, 220.

### Eighth Embodiment

Next, an eighth embodiment of the present invention will be described.

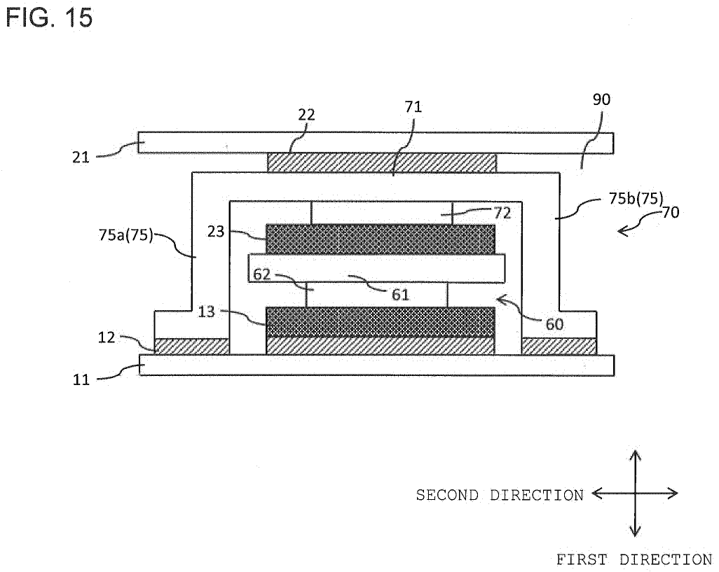

In each of the above embodiments, the second connection body 70 that has the second pillar part 72 having a substantially T-shaped cross section has been described. In the present embodiment, as shown in FIG. 15, the second connection body 70 has extension parts 75 (75a, 75b) extending from the second head part 71 to the other side. Even in the present embodiment, any aspect described in each of the above embodiments can be adopted. The same reference numerals will be used to denote the members described in the above embodiments.

The present embodiment will be described using the aspect in which two extension parts 75 are used. However, the present invention is not limited thereto, and one or three or more extension parts 75 may be used.

According to the present embodiment, since the extension part 75 is provided, the heat from the second electronic element 23 can be dissipated efficiently and the second connection body 70 can realize a high heat dissipation effect. In addition, in the case where a plurality of extension parts 75 is provided as in the present embodiment, it is advantageous in that higher heat dissipation effect can be realized.

By using the second connection body 70 having a plurality of extension parts 75 as in the present embodiment, positioning in the first direction inside the peripheries of the substrates 11, 21 can be more reliably performed. In particular, in the case of adopting protrusion parts 211, 221 and adopting a second connection body 70 having a plurality of extension parts 75, positioning can be performed in the first direction inside the peripheries of the substrates 11, 21 by the second connection body 70 having a plurality of extension parts 75 while positioning is performed in the first direction in the circumferential parts of the substrates 11, 21 by the protrusion parts 211, 221. Therefore, it is advantageous in that it is possible to more reliably prevent the substrate from being warped or distorted even in the case of adopting large substrates 11, 21 in the surface direction.

As in the fourth embodiment, even when adopting an aspect in which the tip of the positioning members 210, 220 is tapered and the distance between the second positioning members 220 provided on the opposing sides is smaller than that of the substrates 11, 21, positioning can be performed in the first direction inside the peripheries of the substrates 11, 21 by the second connection body 70 while positioning is performed in the first direction in the circumferential parts of the substrates 11, 21 by the tip parts of the positioning member 210, 220.

The above description of each embodiment and the disclosure of the drawings are merely examples for describing the invention described in the claims, and the invention described in the claims is not to be limited by the description of the above-mentioned embodiments or the drawings. In addition, the description of the claim as filed is merely an example, and the recitation of the claims can be appropriately changed based on the description of the specification, the drawings, and the like.

### REFERENCE SIGNS LIST

5 conductive adhesive
11 first substrate
13 first electronic element
21 second substrate
23 second electronic element
200 positioning part
210 first positioning member
211 first protrusion part
220 second positioning member
221 second protrusion part
240 bonding material

1. An electronic module comprising:
a first substrate;
an electronic element provided on one side of the first substrate;
a second substrate provided on one side of the electronic element; and
a positioning part extending from the first substrate to one side and abutting a circumferential part of the second substrate, or extending from the second substrate to the other side and abutting against a circumferential part of the first substrate, wherein
the positioning part is formed of a lead frame, and
the positioning part has a lead frame proximal end part extending in a surface direction, and a lead frame extension part provided on the lead frame proximal end part via a lead frame bent part and extending to one side or the other side.

2. The electronic module according to claim 1, wherein
the positioning part has a protrusion part protruding inwardly,
when the positioning part extends from the first substrate to one side and abuts the circumferential part of the second substrate, the protrusion part abuts a surface of the other side of the second substrate, and
when the positioning part extends from the second substrate to the other side and abuts against the circumferential part of the first substrate, the protrusion part abuts a surface of one side of the first substrate.

3. The electronic module, according to claim 2, further comprising
a first conductive layer provided on one side of the first substrate; and
a second conductive layer provided on the other side of the second substrate, and wherein
when the positioning part extends from the first substrate to one side and abuts the circumferential part of the second substrate, the protrusion part abuts a circumferential part of the second conductive layer, and
when the positioning part extends from the second substrate to the other side and abuts against the circumferential part of the first substrate, the protrusion part abuts a circumferential part of the first conductive layer.

4. The electronic module according to claim 1 wherein a tip of the positioning part is tapered.

5. (canceled)

6. (canceled)

7. (canceled)

8. The electronic module according to claim 1, wherein
the electronic element has a first electronic element and a second electronic element provided on one side of the first electronic element, and
a first connection body is provided between the first electronic element and the second electronic element, the first connection body electrically connecting the first electronic element with the second electronic element.
